(19) United States
(12) Patent Application Publication
(10) Pub. No.: US 2025/0192690 A1
(43) Pub. Date: Jun. 12, 2025

(54) POWER CONVERSION DEVICE

(71) Applicant: Mitsubishi Electric Corporation, Chiyoda-ku, Tokyo (JP)

(72) Inventors: Kentaro SHIOURA, Chiyoda-ku, Tokyo (JP); Takeshi YAMAMOTO, Chiyoda-ku, Tokyo (JP)

(73) Assignee: Mitsubishi Electric Corporation, Chiyoda-ku, Tokyo (JP)

(21) Appl. No.: 18/840,711

(22) PCT Filed: Mar. 29, 2022
(86) PCT No.: PCT/JP2022/015717

§ 371 Date: Aug. 22, 2024

(51) Int. Cl. H02M 7/00; B60R 16/03; H02M 1/32; H02M 1/44

(52) U.S. Cl. CPC H02M 7/003; B60R 16/03; H02M 1/327; H02M 1/44; B60Y 2200/30

(57) ABSTRACT

A power conversion device includes a first electronic component group including a plurality of electronic components and a second electronic component group including a plurality of electronic components each having a shorter maintenance cycle than each of the plurality of electronic components included in the first electronic component group. The first electronic component group and the second electronic component group are accommodated in a housing. At least one of the plurality of electronic components included in the second electronic component group is located adjacent to an opening in the housing.

### TECHNICAL FIELD

The present disclosure relates to a power conversion device.

### BACKGROUND ART

A railway vehicle includes a power conversion device that converts power supplied from a power supply to power to be supplied to a load device, for example, lighting equipment or an air conditioning device, and supplies the resulting power to the load device. An example of such a power conversion device is described in Patent Literature 1. The power conversion device described in Patent Literature 1 is installed under the floor of a vehicle together with other in-vehicle devices, for example, a brake controller and a battery.

### CITATION LIST

### Patent Literature

Patent Literature 1: Unexamined Japanese Patent Application Publication No. 2007-182208

### SUMMARY OF INVENTION

### Technical Problem

The power conversion device installed on the railway vehicle includes electronic components having different maintenance cycles. When an electronic component having a short maintenance cycle is located near the middle portion of the railway vehicle in the width direction, the electronic component has a long distance to an opening for maintenance and inspection in a housing of the power conversion device. This complicates the maintenance operation of the electronic component and lowers the maintainability of the power conversion device. This issue is common to any power conversion device including multiple electronic components with different maintenance cycles, as well as to the power conversion device installable under the floor of the vehicle.

Under such circumstances, an objective of the present disclosure is to provide a power conversion device with high maintainability.

### Solution to Problem

To achieve the above objective, a power conversion device according to an aspect of the present disclosure includes a first electronic component group, a second electronic component group, and a housing. The first electronic component group includes a plurality of electronic components. The second electronic component group includes a plurality of electronic components each having a shorter maintenance cycle than each of the plurality of electronic components included in the first electronic component group. The housing accommodates the first electronic component group and the second electronic component group. The housing has an opening. At least one of the plurality of electronic components included in the second electronic component group is located adjacent to the opening.

### Advantageous Effects of Invention

In the power conversion device according to the above aspect of the present disclosure, at least one of the electronic components included in the second electronic component group and each having a shorter maintenance cycle than each of the electronic components included in the first electronic component group is located adjacent to the opening in the housing. The power conversion device can thus have high maintainability.

### BRIEF DESCRIPTION OF DRAWINGS

FIG. 1 is a block diagram illustrating a power conversion device according to Embodiment 1;

FIG. 2 illustrates a railway vehicle provided with the power conversion device according to Embodiment 1;

FIG. 3 illustrates structure of a housing of the power conversion device according to Embodiment 1;

FIG. 4 illustrates arrangement of components of the power conversion device according to Embodiment 1;

FIG. 5 illustrates heat transfer in the power conversion device according to Embodiment 1;

FIG. 6 illustrates heat transfer in the power conversion device according to Embodiment 1;

FIG. 7 illustrates heat transfer in the power conversion device according to Embodiment 1;

FIG. 8 illustrates structure of a housing of a power conversion device according to Embodiment 2;

FIG. 9 illustrates arrangement of components of the power conversion device according to Embodiment 2;

FIG. 10 is a block diagram of a power conversion device according to Embodiment 3;

FIG. 11 illustrates arrangement of components of the power conversion device according to Embodiment 3;

FIG. 12 illustrates heat transfer in the power conversion device according to Embodiment 3;

FIG. 13 illustrates heat transfer in the power conversion device according to Embodiment 3;

FIG. 14 illustrates heat transfer in the power conversion device according to Embodiment 3; and

FIG. 15 illustrates arrangement of components of a power conversion device according to a modification of the embodiments.

### DESCRIPTION OF EMBODIMENTS

A power conversion device according to one or more embodiments of the present disclosure is described below in detail with reference to the drawings. Components identical or corresponding to each other are provided with the same reference sign in the drawings.

### Embodiment 1

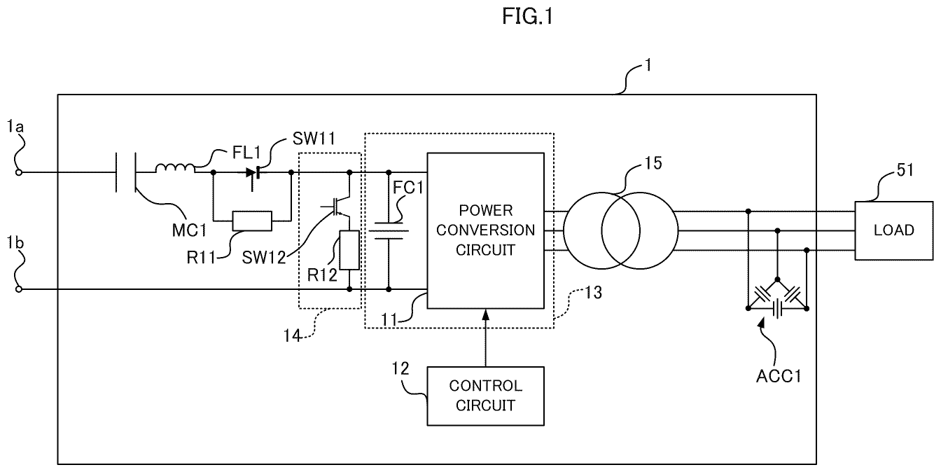

In Embodiment 1 described below, a power conversion device 1 is, for example, a power conversion device serving as an auxiliary power supply installed on a railway vehicle to supply power to a load device, for example, lighting equipment or an air conditioning device. The power conversion device 1 illustrated in FIG. 1 converts power supplied from a non-illustrated power supply to power to be supplied to a load device 51 and supplies the resulting power to the load device 51.

The power conversion device 1 includes an input terminal 1a connected to the power supply, more specifically, to a current collector, an input terminal 1b that is grounded, and a power conversion circuit 11 that converts direct current (DC) power supplied from the power supply to alternating current (AC) power. The current collector receives power from an electrical substation through a power line. For example, the current collector is a pantograph or a current collector shoe, and the power line is an overhead power line or a third rail.

The power conversion device 1 further includes a control circuit 12 that controls switching elements included in the power conversion circuit 11 and a filter capacitor FC1 connected between the primary terminals of the power conversion circuit 11, more specifically, between terminals near the power supply. The power conversion circuit 11 and the filter capacitor FC1 are collectively referred to as a power unit 13.

The power conversion device 1 further includes a contactor MC1 having one end connected to the input terminal 1a, a filter reactor FL1 having one end connected to the contactor MC1, a first switch SW11 having one end connected to the other end of the filter reactor FL1 and the other end connected to the power conversion circuit 11, a charging resistor R11 connected in parallel to the first switch SW11, and a discharge circuit 14 connected in parallel to the filter capacitor FC1. The discharge circuit 14 includes a second switch SW12 and a discharging resistor R12 that are connected in series. The power conversion device 1 further includes a transformer 15 that transforms AC power output from the power conversion circuit 11 and an AC capacitor ACC1 connected to the secondary terminals of the transformer 15.

The contactor MC1 is located between the power conversion circuit 11 and the power supply to open or close the electric path. The contactor MC1 is a DC electromagnetic contactor that is turned on or off by a non-illustrated contactor controller. When turned on, the contactor MC1 electrically connects the input terminal 1a to the filter reactor FL1. This electrically connects the power conversion circuit 11 to the power supply. When turned off, the contactor MC1 electrically disconnects the input terminal 1a from the filter reactor FL1. This electrically disconnects the power conversion circuit 11 from the power supply.

The filter reactor FL1 and the filter capacitor FC1 together serve as an inductor-capacitor (LC) filter to reduce harmonic components generated by a switching operation of the power conversion circuit 11. The filter reactor FL1 also reduces, for example, ripple voltage in an output from electronic components including a rectifier in the electrical substation.

The first switch SW11 is turned on or off by a non-illustrated switch controller. When the contactor MC1 is turned on with the first switch SW11 being on, a current flows from the input terminal 1a, through the contactor MC1, the filter reactor FL1, and the first switch SW11, and to the power conversion circuit 11 and the filter capacitor FC1. When the contactor MC1 is turned on with the first switch SW11 being off, a current flows from the input terminal 1a, through the contactor MC1, the filter reactor FL1, and the charging resistor R11, and to the power conversion circuit 11 and the filter capacitor FC1. The first switch SW11 is, for example, a thyristor.

The charging resistor R11 suppresses an inrush current flowing through the power conversion circuit 11 at the start of the operation of the power conversion device 1. The resistance value of the charging resistor R11 is set to suppress an inrush current flowing through the power conversion circuit 11.

The filter capacitor FC1 is located between the primary terminals of the power conversion circuit 11 and is charged with the DC power supplied from the power supply.

The power conversion circuit 11 converts the DC power supplied through the primary terminals to three-phase AC power and outputs the three-phase AC power to the transformer 15. The power conversion circuit 11 outputs, for example, three-phase AC power with a fixed voltage and a fixed frequency. The power conversion circuit 11 includes multiple switching elements such as insulated-gate bipolar transistors (IGBTs) and converts the DC power to three-phase AC power with switching operations of IGBTs.

Upon receiving an operation command instructing the power conversion device 1 to operate or stop, the control circuit 12 generates control commands for controlling the switching elements included in the power conversion circuit 11 based on the operation command, and transmits the control commands to the switching elements included in the power conversion circuit 11, more specifically, to the gate terminals of the IGBTs.

The second switch SW12 in the discharge circuit 14 is controlled by the switch controller. When the second switch SW12 is turned on with the contactor MC1 being off, the discharging resistor R12 is electrically connected to the filter capacitor FC1 to discharge the filter capacitor FC1. With the second switch SW12 being off, the discharging resistor R12 is electrically disconnected from the filter capacitor FC1.

The transformer 15 is, for example, a delta-star connection transformer that transforms AC power supplied to the primary terminals from the power conversion circuit 11 to a voltage appropriate for the load device 51 and outputs the resulting AC power through the secondary terminals.

The AC capacitor ACC1 is connected to the secondary terminals of the transformer 15. The AC capacitor ACC1 and coils in the transformer 15 together serve as an LC filter to reduce harmonic components generated by a switching operation of the power conversion circuit 11.

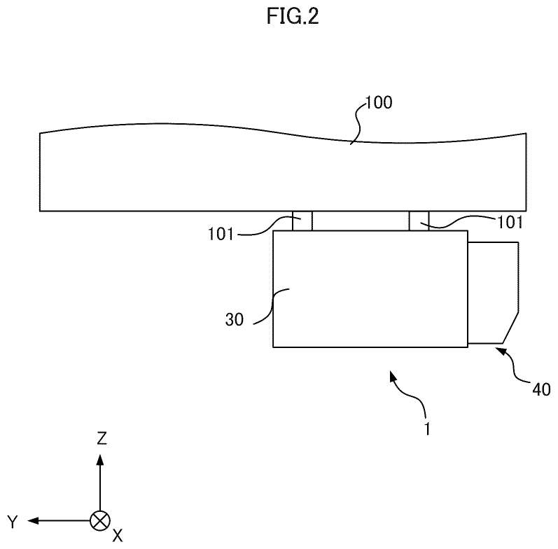

The components of the power conversion device 1 described above are accommodated in a housing 30. As illustrated in FIG. 2, the housing 30 is installed under the floor of a vehicle body 100 of the railway vehicle with mount members 101. The power conversion device 1 further includes a cooling device 40 thermally connected to the power unit 13 accommodated in the housing 30. The cooling device 40 dissipates heat transferred from the power unit 13 to ambient air to cool the power unit 13. In FIG. 2, an X-axis indicates the traveling direction of the railway vehicle, and a Y-axis indicates the width direction of the vehicle body 100. The X-axis, the Y-axis, and a Z-axis are perpendicular to one another. The Z-axis indicates the vertical direction when the railway vehicle is located horizontally. The same applies to subsequent figures.

The housing 30 is formed from a material that has rigidity enough to resist deformation under the vibration generated by the traveling railway vehicle. The housing 30 is attached to the vehicle body 100 firmly enough to maintain the relative positional relationship between the vehicle body 100 and the housing 30 under the vibration generated by the traveling railway vehicle. The housing 30 is preferably formed from a highly thermally conductive material, for example, a metal material. The housing 30 formed from a highly thermally conductive material can transfer heat from the electronic components accommodated in the housing 30 to air outside the housing 30 to cool the electronic components. The housing 30 is formed from, for example, aluminum.

The components of the power conversion device 1, more specifically, the electronic components included in the power conversion device 1, have different maintenance cycles. In Embodiment 1, the multiple electronic components included in the power conversion device 1 are divided into a first electronic component group of multiple electronic components having longer maintenance cycles and a second electronic component group of multiple electronic components having shorter maintenance cycles. In other words, the electronic components included in the second electronic component group each have a shorter maintenance cycle than each electronic component included in the first electronic component group.

The electronic components are determined to be included in the first electronic component group or in the second electronic component group based on the maintenance cycle of each electronic component. The maintenance cycle of each electronic component is, for example, a value acquired by multiplying the designed service life of the electronic component by 0.8. The second electronic component group includes electronic components having shorter maintenance cycles, more specifically, electronic components that perform switching operations, involve mechanical operations, or have higher failure rates.

For example, the second electronic component group includes electronic components having maintenance cycles less than three years, and the first electronic component group includes electronic components having maintenance cycles more than or equal to three years. More specifically, of the components of the power conversion device 1 illustrated in FIG. 1, the first electronic component group includes the filter reactor FL1, the first switch SW11, the AC capacitor ACC1, and the transformer 15, and the second electronic component group includes the contactor MC1, the charging resistor R11, the power unit 13, the control circuit 12, and the discharge circuit 14.

Of the electronic components included in the first electronic component group and the second electronic component group, the electronic components except the transformer 15 are accommodated in the housing 30. In Embodiment 1, the transformer 15 is accommodated in a non-illustrated housing different from the housing 30.

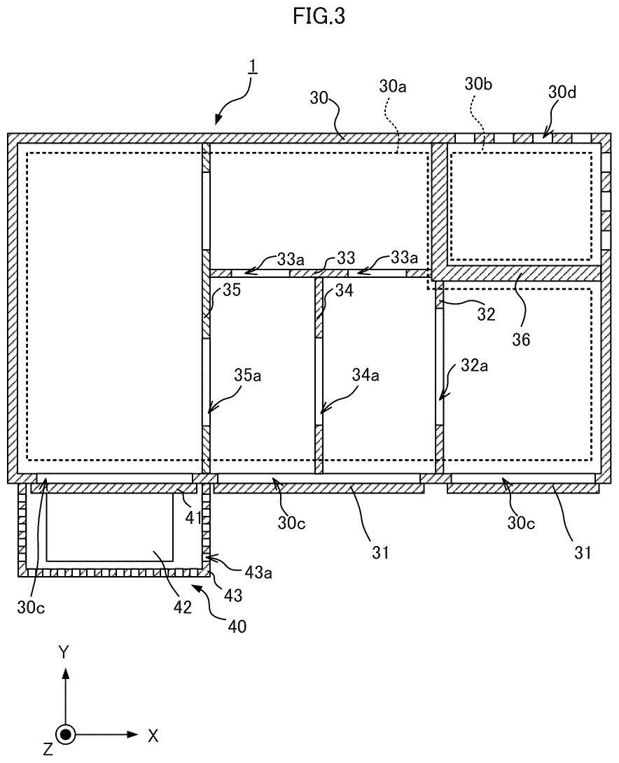

As illustrated in FIG. 3, the housing 30 includes, in the internal space, first partition members 32, 33, 34, and 35 and a second partition member 36. The first partition members 32, 33, 34, and 35 are located between adjacent electronic components of the electronic components included in the first electronic component group and the electronic components included in the second electronic component group and divide the internal space of the housing 30. The second partition member 36 divides the internal space of the housing 30 into a first space 30a and a second space 30b.

The first partition members 32, 33, 34, and 35 are preferably plates with vents 32a, 33a, 34a, and 35a, respectively. The second partition member 36 is preferably a bent plate having an L-shaped cross section perpendicular to the Z-axis direction.

The housing 30 has, in the surface located in the negative Y-axis direction, multiple openings 30c that allow maintenance of the components of the power conversion device 1. The power conversion device 1 further includes multiple openable covers 31 each covering the corresponding opening 30c. Similarly to the housing 30, the covers 31 are formed from a material that has rigidity enough to resist deformation under the vibration generated by the traveling railway vehicle. In Embodiment 1, the structure with the multiple openings 30c allows maintenance of the components of the power conversion device 1 through the openings 30c when the covers 31 are open. The covers 31 preferably have the same thermal conductivity as the housing 30. This allows heat transfer from the electronic components accommodated in the housing 30 to air outside the covers 31, thus cooling the electronic components accommodated in the housing 30. The covers 31 are formed from, for example, aluminum.

The opening 30c at the end of the housing 30 in the negative X-axis direction is covered with the cooling device 40 thermally connected to the electronic components accommodated in the housing 30.

The first space 30a is in contact with a surface having the openings 30c. With the openings 30c in the housing 30 covered with the covers 31 and the cooling device 40, air outside the housing 30 including, for example, dust and moisture is less likely to flow into the first space 30a.

The surfaces of the housing 30 in contact with the second space 30b, more specifically, the surfaces of the housing 30 perpendicular to the Y-axis direction or the X-axis direction in FIG. 3 have vents 30d in portions facing the second partition member 36. The vents 30d allow outside air to flow in and inflow air to flow out. The surfaces of the housing 30 that are not illustrated in FIG. 3 and intersect with the Z-axis direction also have vents 30d in portions in contact with the second space 30b. This allows air outside the housing 30 to flow into the second space 30b.

When, for example, the railway vehicle travels in the positive X-axis direction, air flows into the second space 30b through the vents 30d in the surface of the housing 30 perpendicular to the X-axis direction. The air flowing into the second space 30b through the vents 30d flows in the negative X-axis direction and receives heat from the electronic component accommodated in the second space 30b. The air is then guided along the second partition member 36 to the vents 30d in the surface of the housing 30 perpendicular to the Y-axis direction and flows out of the housing 30 through the vents 30d. When the railway vehicle stops, air flows into the second space 30b through the vents 30d in the vertically lower surface of the housing 30. The air then flows vertically upward and flows out of the housing 30 through the vents 30d in the vertically upper surface of the housing 30.

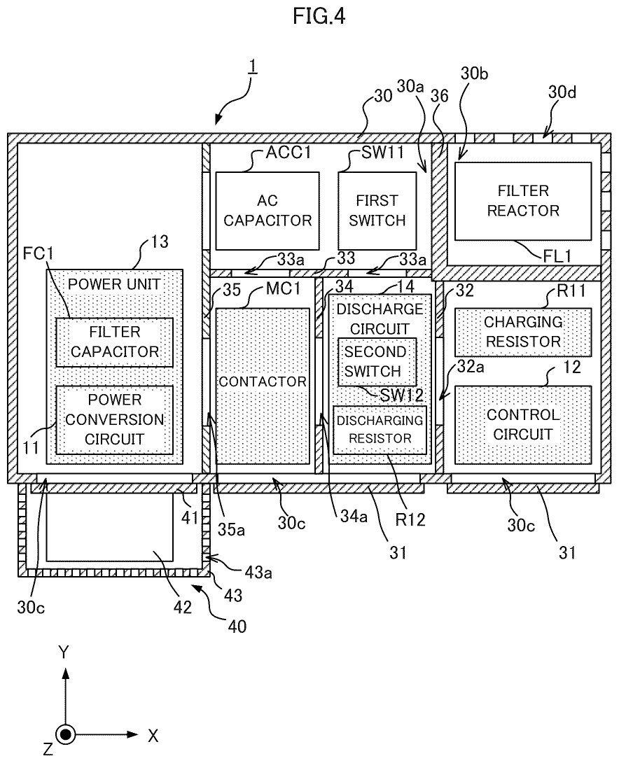

FIG. 4 illustrates the electronic components of the power conversion device 1 that are accommodated in the housing 30 illustrated in FIG. 3. In FIG. 4, the electronic components included in the second electronic component group are filled with a dot pattern. The same applies to the subsequent figures. In the first space 30a, at least one component included in the second electronic component group is located adjacent to at least one of the openings 30c in the housing 30. More specifically, the power unit 13, the contactor MC1, the discharge circuit 14, and the control circuit 12 are each located adjacent to the corresponding opening 30c.

As illustrated in FIGS. 2 and 4, the openings 30c are located in the surface at the end in the Y-axis direction in a vertically lower portion of the vehicle body 100. The electronic components included in the second electronic component group and having shorter maintenance cycles are each located adjacent to the corresponding opening 30c at the end in the Y-axis direction in the vertically lower portion of the vehicle body 100. This structure facilitates maintenance of the electronic components included in the second electronic component group through the openings 30c. The power conversion device 1 thus has high maintainability.

When the railway vehicle travels, passing air that is an airflow in the direction opposite to the traveling direction of the railway vehicle flows along the surface of the housing 30 having the openings 30c and the covers 31 covering the openings 30c without being blocked by other in-vehicle devices. Thus, heat generated by the electronic components included in the second electronic component group and located adjacent to the openings 30c is transferred to the housing 30 and the covers 31 and then transferred from the housing 30 and the covers 31 to the passing air flowing along the housing 30 and the covers 31. This cools the electronic components.

When energized, the electronic components included in the power conversion device 1 each generate heat, but at different rates from one another. For example, the second electronic component group includes multiple low-temperature electronic components that generate heat when energized and multiple high-temperature electronic components that generate more heat per unit time than each of the low-temperature electronic components when energized. Each electronic component is determined as a low-temperature electronic component or as a high-temperature electronic component based on the maximum value of heat generated by the electronic component per unit time. For example, an electronic component having a maximum heat generation value of 100 W or more per unit time is determined as a high-temperature electronic component, and an electronic component having a maximum heat generation value of less than 100 W per unit time is determined as a low-temperature electronic component. More specifically, of the electronic components included in the second electronic component group, the power unit 13, the control circuit 12, and the charging resistor R11 are high-temperature electronic components, and the contactor MC1 and the discharge circuit 14 are low-temperature electronic components.

At least one of the low-temperature electronic components and at least one of the high-temperature electronic components are preferably located adjacent to the corresponding openings 30c and located adjacent to each other. For example, the power unit 13 may be located adjacent to the contactor MC1 in the X-axis direction. In other words, the power unit 13 and the contactor MC1 may be located adjacent to the corresponding openings 30c and adjacent to each other. For example, the control circuit 12 and the charging resistor R11 may be located adjacent to the discharge circuit 14 in the X-axis direction. In other words, the control circuit 12 and the discharge circuit 14 may be located adjacent to the corresponding openings 30c and adjacent to each other.

The first space 30a includes the first partition members 32, 33, 34, and 35. More specifically, the first partition member 32 separates the control circuit 12 and the charging resistor R11 from the discharge circuit 14. The first partition member 32 has the vent 32a. The first partition member 33 separates the first switch SW11 and the AC capacitor ACC1 from the contactor MC1 and the discharge circuit 14. The first partition member 33 has the vents 33a. The first partition member 34 separates the contactor MC1 from the discharge circuit 14. The first partition member 34 has the vent 34a. The first partition member 35 separates the AC capacitor ACC1 and the contactor MC1 from the power unit 13. The first partition member 35 has the vents 35a.

The first partition members 32, 33, 34, and 35 are formed from a plate-like heat conductive material, in other words, a highly thermally conductive material such as aluminum. This allows heat transfer between electronic components adjacent to each other across one of the first partition members 32, 33, 34, or 35.

The vents 32a, 33a, 34a, and 35a in the respective first partition members 32, 33, 34, and 35 allow air convection in the first space 30a.

The second space 30b accommodates the filter reactor FL1. The filter reactor FL1 includes, for example, a coil with an iron core. Air outside the housing 30 flows into the second space 30b through the vents 30d. The air flowing into the second space 30b flows along the coil in the filter reactor FL1 and flows out of the housing 30 through the vents 30d. The filter reactor FL1 transfers heat to the air flowing from outside and is cooled.

The cooling device 40 is attached to the housing 30 and covers the opening 30c in a detachable manner. With the cooling device 40 detached, the maintenance of the power unit 13 can be performed through the opening 30c. The cooling device 40 is thermally connected to the power unit 13. The cooling device 40 includes a base 41 attached to the housing 30, multiple fins 42 attached to the base 41, and a cover 43 covering the base 41 and the multiple fins 42 and attached to the housing 30. The base 41 is preferably formed from a highly thermally conductive material, for example, metal. The base 41 is formed from, for example, aluminum. The cover 43 has vents 43a through which outside air flows into the cover 43 and flows through the fins 42. The multiple fins 42 transfer heat transferred from the power unit 13 through the base 41 to ambient air. This cools the power unit 13.

The operation of the power conversion device 1 with the above structure when energized and the heat transfer between the electronic components are described below. While the power conversion device 1 is energized, electronic components generating more heat preferably each transfer heat, at any appropriate timing, to the corresponding adjacent electronic components generating less heat. This suppresses local temperature increase in the housing 30.

While the railway vehicle is in operation, the power conversion device 1 constantly performs power conversion to supply power to the load device 51. More specifically, when the railway vehicle starts operating, the contactor MC1 illustrated in FIG. 1 is controlled by the contactor controller to be turned on. Immediately after the contactor MC1 is turned on, the first switch SW11 remains off. Thus, a current supplied from the power supply flows through the contactor MC1, the filter reactor FL1, and the charging resistor R11 to the power conversion circuit 11 and the filter capacitor FC1. Immediately after the railway vehicle starts operating, the power conversion circuit 11 and the control circuit 12 are stopped. While the railway vehicle is in operation, the second switch SW12 remains off. Thus, no current flows through the discharging resistor R12 in the discharge circuit 14. While the railway vehicle is in operation, the discharge circuit 14 thus generates no heat.

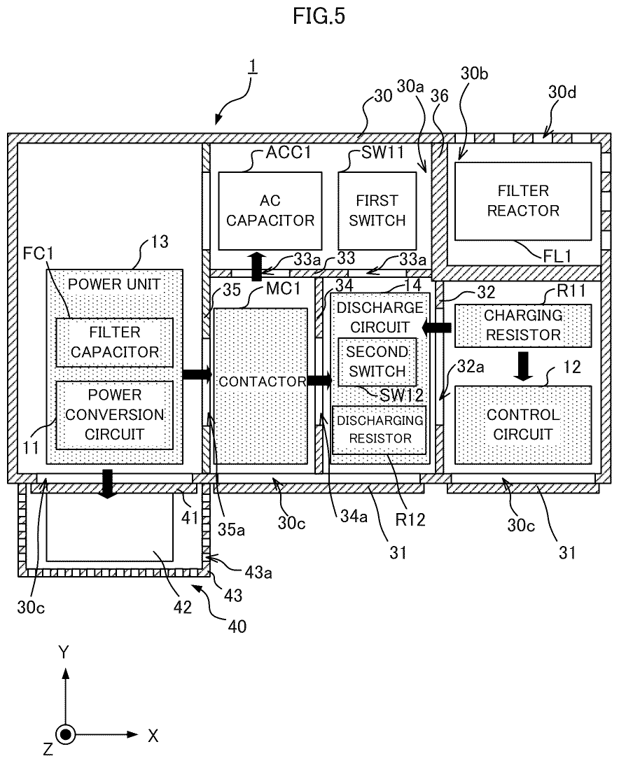

When a current flows as described above, the contactor MC1, the filter reactor FL1, the charging resistor R11, and the filter capacitor FC1 are energized and thus generate heat. As indicated with the solid arrows in FIG. 5, the electronic components generating more heat transfer heat to the electronic components generating less heat. For example, heat radiation or air convection transfers heat among the electronic components. More specifically, the contactor MC1 transfers heat to the adjacent AC capacitor ACC1 and discharge circuit 14, and the charging resistor R11 transfers heat to the adjacent discharge circuit 14 and control circuit 12. The filter capacitor FC1 in the power unit 13 generates heat and transfers heat to the adjacent contactor MC1. With the power unit 13 thermally connected to the cooling device 40, the cooling device 40 partially dissipates heat generated by the filter capacitor FC1 in the power unit 13 to outside air.

The filter reactor FL1 is located in the second space 30b into which air outside the housing 30 flows, and thus is cooled with the air flowing from outside the housing 30 into the second space 30b.

The filter capacitor FC1 is then charged. When the filter capacitor FC1 has a sufficiently high voltage across the terminals, the switch controller turns on the first switch SW11. The filter capacitor FC1 having a sufficiently high voltage across the terminals refers to the filter capacitor FC1 having a voltage across the terminals that has a sufficiently small difference from the voltage of the power supply, more specifically, the voltage of the overhead power line.

When the first switch SW11 is turned on, a current supplied from the power supply flows through the contactor MC1, the filter reactor FL1, and the first switch SW11 to the power conversion circuit 11 and the filter capacitor FC1. With the first switch SW11 being on, no current flows through the charging resistor R11. The charging resistor R11 thus generates no heat. When the first switch SW11 is turned on, the control circuit 12 starts switching on and off the switching elements in the power conversion circuit 11. Thus, the switching elements in the power conversion circuit 11 start switching operations to supply AC power from the power conversion circuit 11 to the transformer 15. The transformer 15 transforms the AC power supplied from the power conversion circuit 11 and supplies the resulting AC power to the load device 51 through the AC capacitor ACC1.

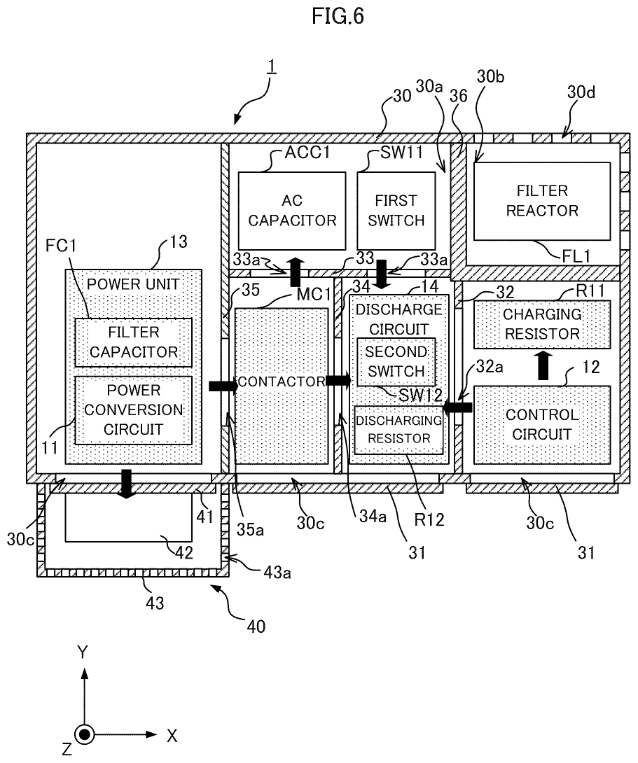

In this state, the contactor MC1, the filter reactor FL1, the first switch SW11, the filter capacitor FC1, the power conversion circuit 11, the control circuit 12, the transformer 15, and the AC capacitor ACC1 are energized and thus generate heat. The contactor MC1, the AC capacitor ACC1, and the first switch SW11 generate less heat per unit time than the power unit 13 and the control circuit 12. The contactor MC1 generates more heat per unit time than the AC capacitor ACC1. As indicated with the solid arrows in FIG. 6, the electronic components generating more heat transfer heat to the electronic components generating less heat.

More specifically, while the railway vehicle is in operation, the high-temperature electronic components included in the second electronic component group transfer heat to the low-temperature electronic components included in the second electronic component group. For example, the power unit 13 transfers heat to the contactor MC1, and the control circuit 12 transfers heat to the discharge circuit 14.

Heat is also transferred between the high-temperature electronic components included in the second electronic component group. With the first switch SW11 being on as described above, the charging resistor R11 generates no heat and thus receives heat from the control circuit 12.

Heat is also transferred between the electronic components included in the first electronic component group and the electronic components included in the second electronic component group. More specifically, the contactor MC1 transfers heat to the AC capacitor ACC1 generating less heat than the contactor MC1. The discharge circuit 14 generates no heat while the railway vehicle is in operation as described above, and thus receives heat from the contactor MC1 and the first switch SW11.

When the railway vehicle ends the operation, the control circuit 12 turns off the switching elements included in the power conversion circuit 11. This stops power supply from the power conversion circuit 11 to the load device 51. The contactor controller then turns off the contactor MC1. This electrically disconnects the power conversion circuit 11 from the power supply. Immediately after the contactor MC1 is turned off, the electronic components that have generated heat while the railway vehicle is in operation have sufficiently high temperatures, thus having heat transfer as in the example illustrated in FIG. 6.

The switch controller then turns on the second switch SW12 to electrically connect the discharging resistor R12 to the filter capacitor FC1 to discharge the filter capacitor FC1.

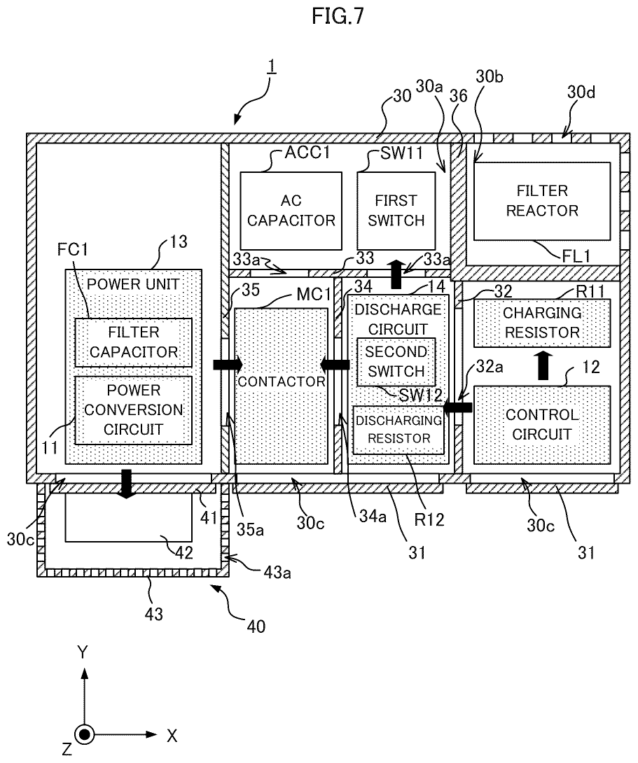

In this state, the second switch SW12 and the discharging resistor R12 in the discharge circuit 14 are energized and thus generate heat. As indicated with the solid arrows in FIG. 7, the electronic components generating more heat thus transfer heat to the electronic components generating less heat. More specifically, the discharge circuit 14 transfers heat to the first switch SW11 and the contactor MC1.

When the power unit 13 and the control circuit 12 have higher temperatures than the other electronic components, the power unit 13 transfers heat to the contactor MC1, and the control circuit 12 transfers heat to the discharge circuit 14 and the charging resistor R11.

As described above, while the power conversion device 1 is energized, the electronic components generating more heat each transfer heat, at any appropriate timing, to the corresponding adjacent electronic component generating less heat. More specifically, heat generated by the high-temperature electronic components included in the second electronic component group is constantly transferred to the low-temperature electronic components included in the second electronic component group and located adjacent to the high-temperature electronic components included in the second electronic component group.

As described above, in the power conversion device 1 according to Embodiment 1, the multiple electronic components included in the second electronic component group having shorter maintenance cycles, more specifically, the power unit 13, the contactor MC1, the discharge circuit 14, and the control circuit 12 are located adjacent to the openings 30c in the housing 30. The power conversion device 1 thus has high maintainability.

The second electronic component group includes the high-temperature electronic components and the low-temperature electronic components located adjacent to the high-temperature electronic components. The high-temperature electronic components generate more heat per unit time than the low-temperature electronic components. Heat is transferred from the high-temperature electronic components to the low-temperature electronic components. Local temperature increase in the internal space of the housing 30 is thus suppressed. This leads to suppression of temperature increase at a specific position in the internal space of the housing 30 and temperature increase in a component at the position.

Some of the electronic components in the power conversion device 1 are located adjacent to one another in the direction in which the openings 30c extend through, that is, in the Y-axis direction. For example, the first switch SW11 and the discharge circuit 14 are located adjacent to each other in the Y-axis direction. This structure allows the housing 30 to have a shorter length in the X-axis direction than in a power conversion device including multiple components aligned in a row. The space under the floor of the vehicle body can thus be used efficiently.

### Embodiment 2

The components of the power conversion device 1 may be arranged in the housing 30 in any manner other than in the above example. A power conversion device 2 including the transformer 15 accommodated in the housing 30 is described in Embodiment 2, focusing on the differences from Embodiment 1.

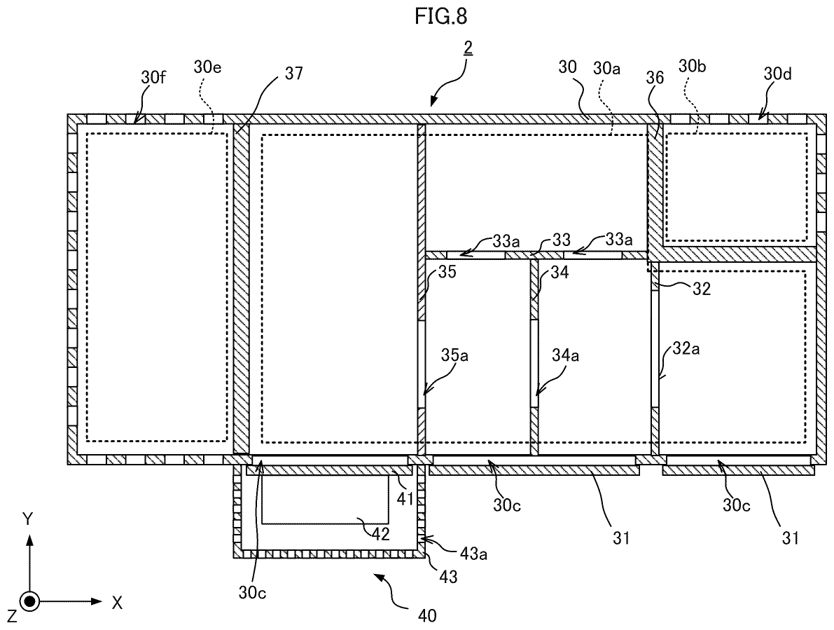

The housing 30 included in the power conversion device 2 illustrated in FIG. 8 has the internal space divided into the first space 30a and the second spaces 30b and 30e by the second partition member 36 and a heat insulation member 37. More specifically, the first space 30a is surrounded by a surface of the second partition member 36 facing in the negative X-axis direction, a surface of the second partition member 36 facing in the negative Y-axis direction, a surface of the heat insulation member 37 facing in the positive X-axis direction, and the housing 30. The second space 30b is surrounded by a surface of the second partition member 36 facing in the positive Y-axis direction, a surface of the second partition member 36 facing in the positive X-axis direction, and the housing 30. The second space 30e is surrounded by a surface of the heat insulation member 37 facing in the negative X-axis direction and the housing 30.

The transformer 15 has a sufficiently longer maintenance cycle than other electronic components included in the power conversion device 2 and thus is included in the first electronic component group. The transformer 15 generates more heat than the control circuit 12 and the power unit 13 and thus is at a position to receive air outside the housing 30. More specifically, the transformer 15 is accommodated in the housing 30 illustrated in FIG. 8, or in the second space 30e surrounded by the surface of the heat insulation member 37 facing in the negative X-axis direction and the housing 30. The housing 30 has vents 30f in the surfaces in contact with the second space 30e, more specifically, in the surfaces perpendicular to the Y-axis direction and in contact with the second space 30e and a surface facing the heat insulation member 37 in FIG. 8. The vents 30f allow outside air to flow in and inflow air to flow out. The housing 30 also has vents 30f, which are not illustrated in FIG. 8, in portions of the surfaces perpendicular to the Z-axis direction and in contact with the second space 30e. This allows air outside the housing 30 to flow into the second space 30e.

When, for example, the railway vehicle travels in the negative X-axis direction, air flows into the second space 30e through the vents 30f in the surface of the housing 30 facing the heat insulation member 37. The air flowing into the second space 30e through the vents 30f flows in the positive X-axis direction and receives heat from the electronic component accommodated in the second space 30e. The air is then guided along the heat insulation member 37 to flow in the positive Y-axis direction or in the negative Y-axis direction to the vents 30f in the surfaces perpendicular to the Y-axis direction in the housing 30 and in contact with the second space 30e. The air then flows out of the housing 30 through the vents 30f. When the railway vehicle stops, air flows into the second space 30e through the vents 30f in the vertically lower surface of the housing 30, and flows vertically upward. The air then flows out of the housing 30 through the vents 30f in the vertically upper surface of the housing 30.

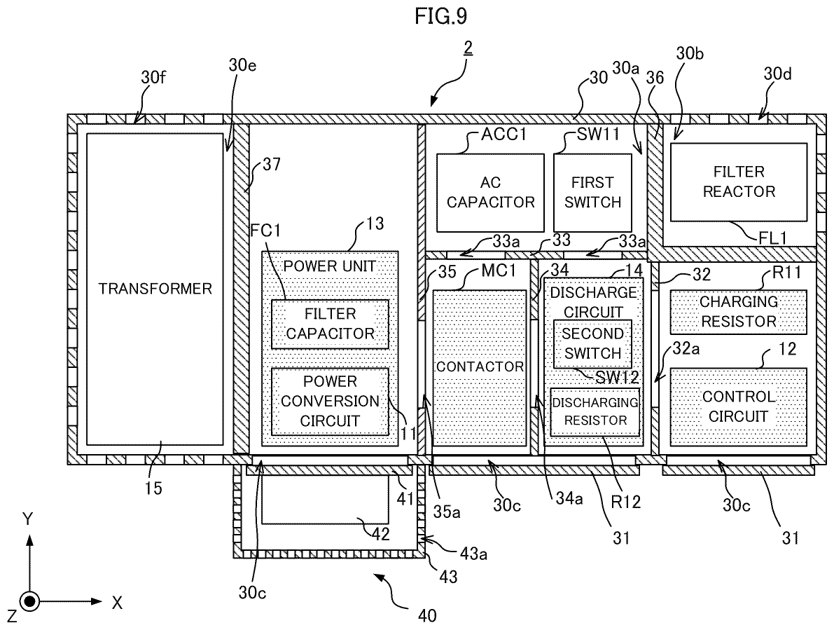

FIG. 9 illustrates the electronic components of the power conversion device 2 that are accommodated in the housing 30 illustrated in FIG. 8. The switching operation of the power conversion circuit 11 generates harmonic components. The harmonic components generate magnetic flux from wiring connecting the power conversion circuit 11 and the transformer 15. In the power conversion device 2 according to Embodiment 2, the housing 30 accommodates the transformer 15, and thus accommodates the wiring connecting the power conversion circuit 11 and the transformer 15. This structure reduces the likelihood that the magnetic flux generated from the wiring connecting the power conversion circuit 11 and the transformer 15 affects other in-vehicle devices.

The heat insulation member 37 is located between the transformer 15 and the power unit 13 adjacent to each other in the X-axis direction to divide the internal space of the housing 30 into the second space 30e including the transformer 15 and the first space 30a including the power unit 13.

The heat insulation member 37 suppresses heat transfer between the electronic components adjacent to each other across the heat insulation member 37. The heat insulation member 37 is formed from, for example, a material having low thermal conductivity such as iron or a resin. The heat insulation member 37 suppresses heat transfer from the transformer 15 having high heat generation to other electronic components having high heat generation, such as the power unit 13. This allows the housing 30 to accommodate the transformer 15 having high heat generation while suppressing internal temperature increase of the other electronic components accommodated in the housing 30.

As described above, in the power conversion device 2 according to Embodiment 2, the housing 30 accommodates the transformer 15. Thus, the magnetic flux generated from the wiring connecting the power conversion circuit 11 and the transformer 15 is less likely to affect other in-vehicle devices.

With the heat insulation member 37 located between the electronic components adjacent to each other, the electronic component having high heat generation is less likely to transfer heat to other electronic components having high heat generation, thus suppressing temperature increase in the other electronic components.

### Embodiment 3

The structure of the power conversion device may be other than in the above examples. A redundant power conversion device 3 is described in Embodiment 3, focusing on the differences from Embodiment 1.

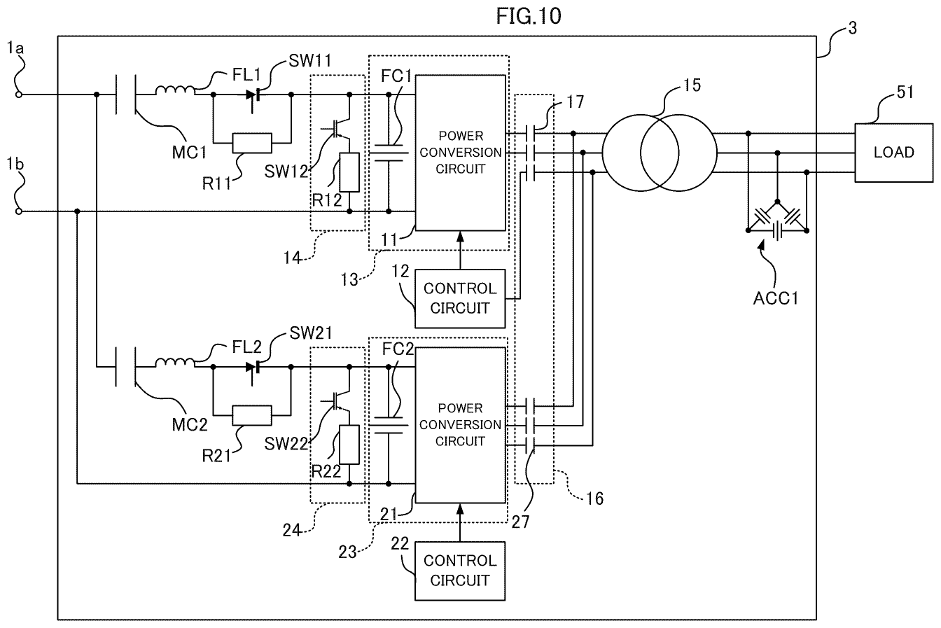

In addition to the components of the power conversion device 1, the power conversion device 3 illustrated in FIG. 10 includes a power conversion circuit 21 that converts DC power supplied from the power supply to AC power, a control circuit 22 that controls switching elements included in the power conversion circuit 21, and a filter capacitor FC2 connected between the primary terminals of the power conversion circuit 21, more specifically, between terminals near the power supply. The power conversion circuit 21 and the filter capacitor FC2 are collectively referred to as a power unit 23.

The power conversion device 3 further includes a contactor MC2 having one end connected to the input terminal 1a, a filter reactor FL2 having one end connected to the contactor MC2, a first switch SW21 having one end connected to the other end of the filter reactor FL2 and the other end connected to the power conversion circuit 21, a charging resistor R21 connected in parallel to the first switch SW21, and a discharge circuit 24 connected in parallel to the filter capacitor FC2. The discharge circuit 24 includes a second switch SW22 and a discharging resistor R22 that are connected in series.

The power conversion device 3 further includes a switching circuit 16 that electrically connects either the power conversion circuit 11 or the power conversion circuit 21 to the transformer 15. The switching circuit 16 includes a switcher 17 to open or close the electric path between the power conversion circuit 11 and the transformer 15 and a switcher 27 to open or close the electric path between the power conversion circuit 21 and the transformer 15.

The contactor MC2 is located between the power conversion circuit 21 and the power supply to open or close the electric path. The contactor MC2 is a DC electromagnetic contactor that is turned on or off by a contactor controller. When turned on, the contactor MC2 electrically connects the input terminal 1a to the filter reactor FL2. This electrically connects the power conversion circuit 21 to the power supply. When turned off, the contactor MC2 electrically disconnects the input terminal 1a from the filter reactor FL2. This electrically disconnects the power conversion circuit 21 from the power supply.

The filter reactor FL2 and the filter capacitor FC2 together serve as an LC filter to reduce harmonic components generated by the switching operation of the power conversion circuit 21.

The first switch SW21 is turned on or off by a switch controller. When the contactor MC2 is turned on with the first switch SW21 being on, a current flows from the input terminal 1a through the contactor MC2, the filter reactor FL2, and the first switch SW21 to the power conversion circuit 21. When the contactor MC2 is turned on with the first switch SW21 being off, a current flows from the input terminal 1a through the contactor MC2, the filter reactor FL2, and the charging resistor R21 to the power conversion circuit 21. The first switch SW21 is, for example, a thyristor.

The charging resistor R21 suppresses an inrush current flowing through the power conversion circuit 21 at the start of the operation of the power conversion device 3. The resistance value of the charging resistor R21 is set to suppress an inrush current flowing through the power conversion circuit 21.

The filter capacitor FC2 is located between the primary terminals of the power conversion circuit 21 and is charged with the DC power supplied from the power supply.

The power conversion circuit 21 converts the DC power supplied through the primary terminals to three-phase AC power and outputs the three-phase AC power to the transformer 15. The power conversion circuit 21 outputs, for example, three-phase AC power with a fixed voltage and a fixed frequency. The power conversion circuit 21 includes multiple switching elements, such as IGBTs, and converts DC power to three-phase AC power through the switching operations of the IGBTs.

Upon receiving an operation command instructing the power conversion device 3 to operate or stop, the control circuit 22 generates control commands for controlling switching elements included in the power conversion circuit 21 in accordance with the operation command, and transmits the control commands to the switching elements included in the power conversion circuit 21, more specifically, to the gate terminals of the IGBTs.

The second switch SW22 in the discharge circuit 24 is controlled by the switch controller. When the second switch SW22 is turned on with the contactor MC2 being off, the discharging resistor R22 is electrically connected to the filter capacitor FC2 to discharge the filter capacitor FC2. When the second switch SW22 is off, the discharging resistor R22 is electrically disconnected from the filter capacitor FC2.

Of the components of the power conversion device 3 illustrated in FIG. 10, the first electronic component group includes the filter reactors FL1 and FL2, the first switches SW11 and SW21, the switching circuit 16 including the switchers 17 and 27, the AC capacitor ACC1, and the transformer 15, and the second electronic component group includes the contactors MC1 and MC2, the charging resistors R11 and R21, the power units 13 and 23, the control circuits 12 and 22, and the discharge circuits 14 and 24.

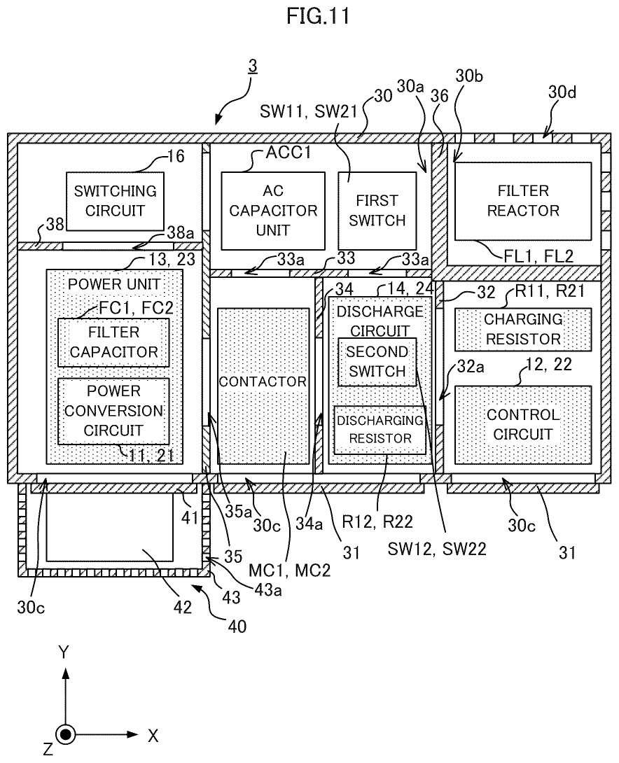

The components of the power conversion device 3 described above are accommodated in the housing 30. As illustrated in FIG. 11, the power conversion device 3 further includes a first partition member 38 in addition to the components of the power conversion device 1 illustrated in FIG. 4.

The first partition member 38 separates the switching circuit 16 from the power units 13 and 23. The first partition member 38 is formed from a heat conductive material, in other words, a highly thermally conductive material such as aluminum. The first partition member 38 has a vent 38a.

The components of the power conversion device 3 are arranged in the same manner as in Embodiment 1. The redundant electronic components are each located at the same corresponding position in the housing 30.

The operation of the power conversion device 3 with the above structure when energized is described below. In the power conversion device 3, one of the power conversion circuits 11 and 21 is set as an operating system, and the other is set as a standby system. In other words, while the power conversion device 3 is operating, one of the power conversion circuits 11 and 21 performs power conversion, and the other stops. The power conversion device 3 with the power conversion circuit 11 set as an operating system operates in the same manner as in Embodiment 1. However, after the contactor MC1 is turned on, a non-illustrated switching circuit controller turns on the switcher 17 in the switching circuit 16 to electrically connect the power conversion circuit 11 to the transformer 15.

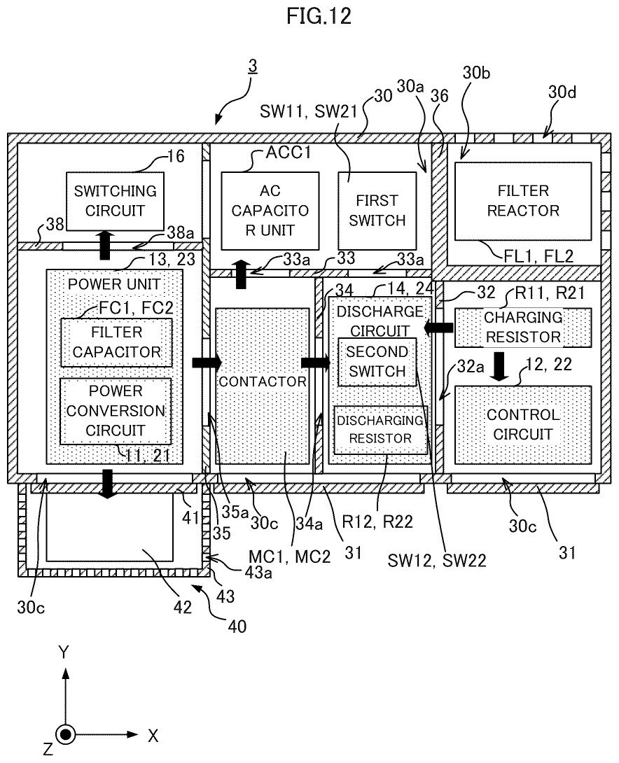

When the railway vehicle starts operating, the contactor MC1 is turned on, as in Embodiment 1. The contactor MC1, the filter reactor FL1, the charging resistor R11, and the filter capacitor FC1 are then energized and thus generate heat. As indicated with the solid arrows in FIG. 12, the electronic components generating more heat transfer heat to the electronic components generating less heat.

More specifically, the contactor MC1 transfers heat to the adjacent AC capacitor ACC1 and discharge circuit 14, and the charging resistor R11 transfers heat to the adjacent discharge circuit 14 and control circuit 12. The filter capacitor FC1 in the power unit 13 generates heat and transfers the heat to the adjacent contactor MC1 and switching circuit 16. With the power unit 13 thermally connected to the cooling device 40, the cooling device 40 partially dissipates heat generated by the filter capacitor FC1 in the power unit 13 to outside air.

As in Embodiment 1, the first switch SW11 is then turned on, and the control circuit 12 starts switching on and off the switching elements in the power conversion circuit 11. The switching elements in the power conversion circuit 11 then start switching operations to supply AC power from the power conversion circuit 11 to the load device 51 through the switcher 17 and the transformer 15.

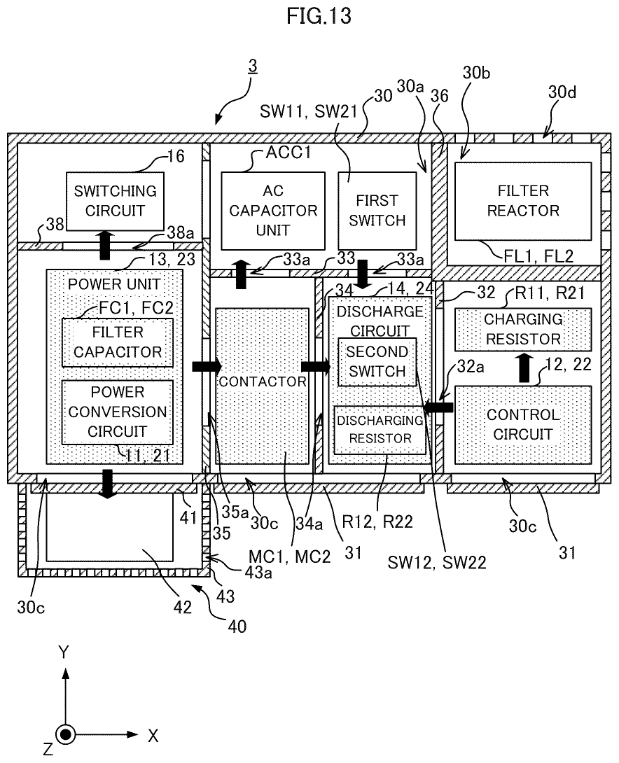

In this state, the contactor MC1, the filter reactor FL1, the first switch SW11, the filter capacitor FC1, the power conversion circuit 11, the control circuit 12, the transformer 15, the switching circuit 16, and the AC capacitor ACC1 are energized and thus generate heat. As indicated with the solid arrows in FIG. 13, the electronic components generating more heat transfer heat to the electronic components generating less heat.

More specifically, while the railway vehicle is in operation, the high-temperature electronic components included in the second electronic component group transfer heat to the low-temperature electronic components included in the second electronic component group. For example, the power unit 13 transfers heat to the contactor MC1 and the switching circuit 16, and the control circuit 12 transfers heat to the discharge circuit 14.

Heat is also transferred between the high-temperature electronic components included in the second electronic component group. With the first switch SW11 being on as described above, the charging resistor R11 generates no heat and thus receives heat from the control circuit 12.

Heat is further transferred between the electronic components included in the first electronic component group and the electronic components included in the second electronic component group. More specifically, the contactor MC1 included in the second electronic component group transfers heat to the AC capacitor ACC1 generating less heat than the contactor MC1 and included in the first electronic component group. The discharge circuit 14 generates no heat while the railway vehicle is in operation as described above, and thus receives heat from the contactor MC1 and the first switch SW11.

When the railway vehicle ends the operation, the control circuit 12 turns off the switching elements included in the power conversion circuit 11 as in Embodiment 1. The switch controller then turns on the second switch SW12 to electrically connect the discharging resistor R12 to the filter capacitor FC1 to discharge the filter capacitor FC1.

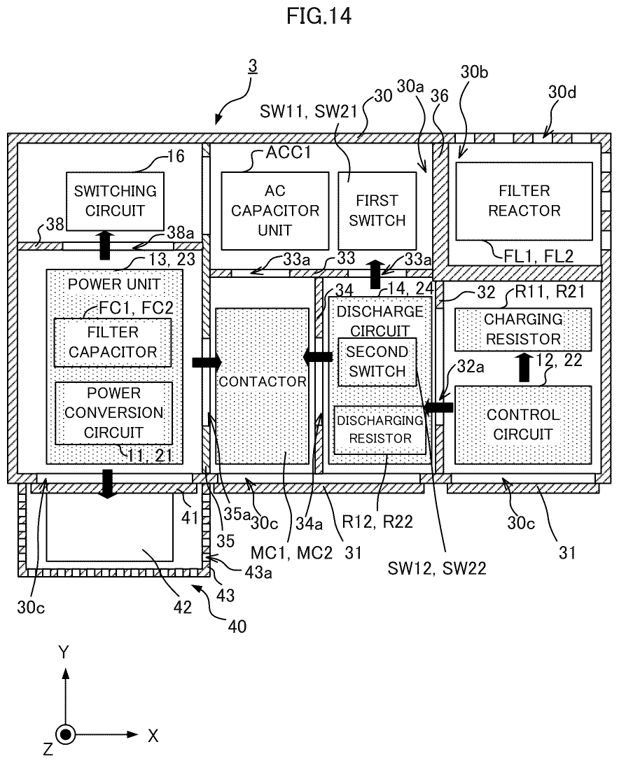

In this state, the second switch SW12 and the discharging resistor R12 in the discharge circuit 14 are energized and thus generate heat. As indicated with the solid arrows in FIG. 14, the electronic components generating more heat thus transfer heat to the electronic components generating less heat. More specifically, the discharge circuit 14 transfers heat to the first switch SW11 and the contactor MC1.

When the power unit 13 and the control circuit 12 have higher temperatures than the other electronic components, the power unit 13 transfers heat to the switching circuit 16 and the contactor MC1, and the control circuit 12 transfers heat to the discharge circuit 14 and the charging resistor R11.

The power conversion circuit 21 set as an operating system operates in the same manner as the power conversion circuit 11 set as an operating system. However, after the contactor MC2 is turned on, the switching circuit controller turns on the switcher 27 in the switching circuit 16 to electrically connect the power conversion circuit 21 to the transformer 15.

As described above, while the power conversion device 3 is energized, the electronic components generating more heat each transfer heat, at any appropriate timing, to the corresponding adjacent electronic component generating less heat. More specifically, heat generated by the high-temperature electronic components included in the second electronic component group is constantly transferred to the low-temperature electronic components included in the second electronic component group and located adjacent to the high-temperature electronic components included in the second electronic component group.

As described above, in the power conversion device 3 according to Embodiment 3, the multiple electronic components included in the second electronic component group having shorter maintenance cycles, more specifically, the power units 13 and 23, the contactors MC1 and MC2, the discharge circuits 14 and 24, and the control circuits 12 and 22 are located adjacent to the openings 30c in the housing 30. The power conversion device 3 thus has high maintainability.

The second electronic component group includes the high-temperature electronic components and the low-temperature electronic components located adjacent to the high-temperature electronic components. The high-temperature electronic components generate more heat per unit time than the low-temperature electronic components. Heat is transferred from the high-temperature electronic components to the low-temperature electronic components. Local temperature increase in the internal space of the housing 30 is thus suppressed. This leads to suppression of temperature increase at a specific position in the internal space of the housing 30 and temperature increase in a component at the position having higher temperature.

The present disclosure is not limited to the above embodiments. The above embodiments may be combined. In one example, the transformer 15 included in the power conversion device 3 may be accommodated in the housing 30 as in the power conversion device 2.

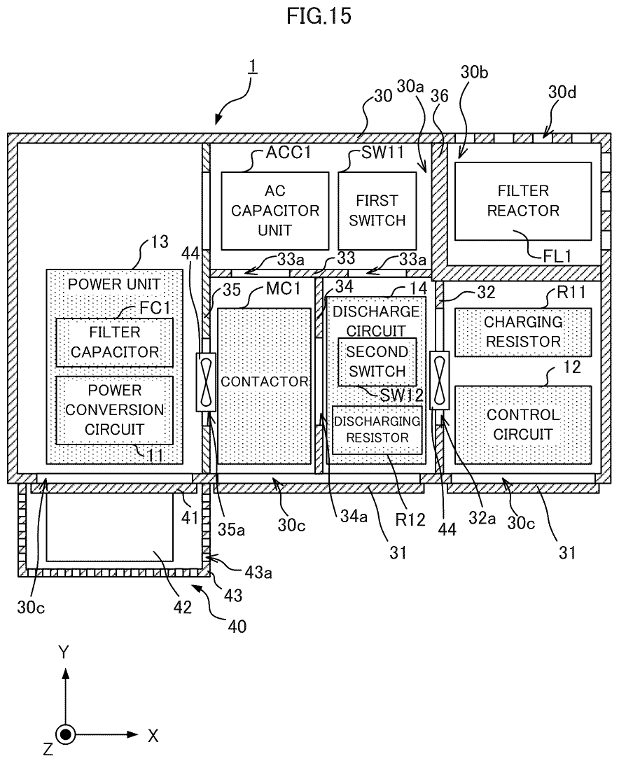

The power conversion devices 1 to 3 may each further include blowers to promote air convection in the housing 30. FIG. 15 illustrates an example of a power conversion device 1 including blowers. The power conversion device 1 includes blowers 44 in the vents 32a and 35a. The blowers 44 operate when, for example, receiving AC power from the power conversion circuit 11. The blowers 44 efficiently transfer heat from the control circuit 12 to the discharge circuit 14 and from the power unit 13 to the contactor MC1. The blowers 44 may be at any positions in the first space 30a other than in the example in FIG. 15. Any number of blowers 44 may be included other than in the example in FIG. 15.

The circuit configurations of the power conversion devices 1 to 3 may be other than in the above examples. In one example, the power conversion devices 1 to 3 may each be a DC-DC converter. In another example, the connection of the transformer 15 may be other than the delta-star connection.

The power conversion devices 1 to 3 may each be installed on an AC feeding railway vehicle, rather than on a DC feeding railway vehicle. When the power conversion device 1, 2, or 3 is installed on an AC feeding railway vehicle, a transformer that lowers the voltage of the AC power received by the current collector and a converter that converts the resulting AC power to DC power are located between the current collector and the power conversion device 1, 2, or 3. The power conversion devices 1 to 3 may each be installed on any movable body such as an automobile, an aircraft, or a ship, rather than on the railway vehicle.

The first partition members 32, 33, 34, 35, and 38 may be at any positions between the electronic components included in the power conversion device 1, 2, or 3, other than at the positions in the above examples. The first partition members 32, 33, 34, 35, and 38 may have any numbers of the vents 32a, 33a, 34a, 35a, and 38a at any positions other than in the above examples.

The housing 30 may be attached to the roof of the vehicle body of a railway vehicle. The housing 30 may have the openings 30c at any positions other than in the above examples.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1, 2, 3 Power conversion device
1a, 1b Input terminal
11, 21 Power conversion circuit
12, 22 Control circuit
13, 23 Power unit
14, 24 Discharge circuit
15 Transformer
16 Switching circuit
17, 27 Switcher
30 Housing
30a First space
30b, 30e Second space
30c Opening
30d, 30f, 32a, 33a, 34a, 35a, 38a, 43a Vent
31 Cover
32, 33, 34, 35, 38 First partition member
36 Second partition member
37 Heat insulation member
40 Cooling device
41 Base
42 Fin
43 Cover
44 Blower
51 Load device
100 Vehicle body
101 Mount member
ACC1 AC capacitor
FC1, FC2 Filter capacitor
FL1, FL2 Filter reactor
MC1, MC2 Contactor
R11, R21 Charging resistor
R12, R22 Discharging resistor
SW11, SW21 First switch
SW12, SW22 Second switch

1. A power conversion device, comprising:
a first electronic component group including a plurality of electronic components;
a second electronic component group including a plurality of electronic components each having a shorter maintenance cycle than each of the plurality of electronic components included in the first electronic component group; and
a housing accommodating the first electronic component group and the second electronic component group, the housing having an opening, wherein
at least one of the plurality of electronic components included in the second electronic component group is located adjacent to the opening,
the plurality of electronic components included in the second electronic component group include a plurality of low-temperature electronic components to generate heat when energized and a plurality of high-temperature electronic components to generate more heat per unit time when energized than each of the plurality of low-temperature electronic components, and
at least one of the plurality of low-temperature electronic components and at least one of the plurality of high-temperature electronic components are located adjacent to the opening and are located adjacent to each other.

2. (canceled)

3. The power conversion device according to claim 1, wherein
at least one of the plurality of electronic components included in the first electronic component group is located adjacent to at least one of the plurality of electronic components included in the second electronic component group in a direction in which the opening extends through.

4. The power conversion device according to claim 1, further comprising:
a first partition member between adjacent electronic components of the plurality of electronic components included in the first electronic component group and the plurality of electronic components included in the second electronic component group, the first partition member being formed from a plate-like heat conductive material and dividing an internal space of the housing.

5. The power conversion device according to claim 4, wherein
the first partition member has a vent.

6. The power conversion device according to claim 5, further comprising:
a blower in the vent in the first partition member.

7. The power conversion device according to claim 1, further comprising:
a heat insulation member between adjacent electronic components of the plurality of electronic components included in the first electronic component group and the plurality of electronic components included in the second electronic component group, the heat insulation member dividing an internal space of the housing.

8. The power conversion device according to claim 1, further comprising:
a power conversion circuit to convert power supplied from a power supply to power to be supplied to a load and output the power resulting from conversion;
a filter capacitor connected between terminals of the power conversion circuit, the terminals being near the power supply;
a control circuit to control a switching element included in the power conversion circuit; and
a contactor between the power conversion circuit and the power supply to open or close an electric path, wherein
the power conversion circuit, the filter capacitor, the control circuit, and the contactor are included in the second electronic component group.

9. The power conversion device according to claim 8, wherein
the power conversion circuit, the filter capacitor, and the contactor are located adjacent to the opening, and the power conversion circuit and the filter capacitor are located adjacent to the contactor.

10. The power conversion device according to claim 8, further comprising:
a discharge circuit connected in parallel to the filter capacitor, the discharge circuit including a second switch and a discharging resistor connected in series to each other, wherein
the discharge circuit is included in the second electronic component group.

11. The power conversion device according to claim 10, wherein
the control circuit and the discharge circuit are located adjacent to the opening and are located adjacent to each other.

12. The power conversion device according to claim 10, further comprising:
a first switch electrically connected to the contactor and the power conversion circuit; and
a charging resistor connected in parallel to the first switch, wherein
the first switch is included in the first electronic component group,
the charging resistor is included in the second electronic component group,
the control circuit, the charging resistor, and the discharge circuit are located adjacent to the opening, and the control circuit and the charging resistor are located adjacent to the discharge circuit, and
the first switch and the discharge circuit are located adjacent to each other in a direction in which the opening extends through.

13. The power conversion device according to claim 10, wherein
the power conversion circuit converts direct current power supplied from the power supply through the filter capacitor to alternating current power to be supplied to the load and outputs the alternating current power resulting from conversion,
the power conversion device further comprises a transformer to transform the alternating current power output by the power conversion circuit and an alternating current capacitor electrically connected to an output end of the transformer, and
the alternating current capacitor and the transformer are included in the first electronic component group.

14. The power conversion device according to claim 13, wherein
the transformer and the power conversion circuit are located adjacent to each other, and
the power conversion device further comprises a heat insulation member located between the transformer and the power conversion circuit and dividing an internal space of the housing.

15. The power conversion device according to claim 8, wherein
the power conversion device comprises a plurality of the power conversion circuits,
the power conversion device further comprises a switching circuit electrically connecting one of the plurality of power conversion circuits to the load, and
the switching circuit is included in the first electronic component group.

16. The power conversion device according to claim 8, further comprising:
a second partition member dividing an internal space of the housing into a first space and a second space, the first space being in contact with a surface having the opening, the second space being a space into which air outside the housing flows.

17. The power conversion device according to claim 16, further comprising:
a first switch electrically connected to the contactor and the power conversion circuit, and
a reactor electrically connected to the first switch and to the power conversion circuit and accommodated in the second space.

18. The power conversion device according to claim 16, further comprising:
a transformer accommodated in the second space to transform alternating current power output by the power conversion circuit.

19. A power conversion device, comprising:
a power conversion circuit to convert power supplied from a power supply to power to be supplied to a load and output the power resulting from conversion;
a first electronic component group including a plurality of electronic components different from the power conversion circuit;
a second electronic component group including a plurality of electronic components each having a shorter maintenance cycle than each of the plurality of electronic components included in the first electronic component group; and
a housing accommodating the first electronic component group and the second electronic component group, the housing having an opening, wherein
the second electronic component group includes the power conversion circuit, and
at least one of the plurality of electronic components included in the second electronic component group is located adjacent to the opening.
